(19) United States
(12) Patent Application Publication
(10) Pub. No.: US 2026/0206132 A1
(43) Pub. Date: Jul. 16, 2026

(54) FLEXIBLE CIRCUIT BOARD, DISPLAY PANEL, AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Feng ZHAN, Beijing (CN); Xu LU, Beijing (CN); An FU, Beijing (CN); Jinxu CHENG, Beijing (CN); Taifeng QING, Beijing (CN); Fuyu CUI, Beijing (CN); Miao LUO, Beijing (CN); Shuqi ZHANG, Beijing (CN); Yishun ZHANG, Beijing (CN)

(21) Appl. No.: 18/866,293

(22) PCT Filed: Aug. 12, 2024
(86) PCT No.: PCT/CN2024/111445

§ 371 Date: Nov. 15, 2024

(30) Foreign Application Priority Data
Sep. 27, 2023 (CN) 202311267494.5

(51) Int. Cl. H05K 1/02

(52) U.S. Cl. CPC H05K 1/0277; H05K 2201/10128

(57) ABSTRACT

The present disclosure relates to a flexible circuit board, a display panel, and a display apparatus. The flexible circuit board includes a substrate, one or more electronic elements, and an adhesive layer. The substrate includes one or more device regions on an upper surface of the substrate, and the electronic elements are fixed in the device regions. The adhesive layer is fixed to a lower surface of the substrate; and the adhesive layer includes an adhesive portion and one or more cavity portions formed by hollowing out a part of the adhesive portion, and the cavity portions are located below the device regions.

### CROSS REFERENCE TO RELATED APPLICATION

The present disclosure is a U.S. national phase of PCT Application No. PCT/CN2024/111445 filed on Aug. 12, 2024, which claims priority to Chinese Patent Application No. 202311267494.5 filed on Sep. 27, 2023, contents of which are hereby incorporated by reference in their entireties.

### TECHNICAL FIELD

The present disclosure relates to a field of display technology, and in particular, to a flexible circuit board, a display panel, and a display apparatus.

### BACKGROUND

A flexible circuit board (FPC), also known as a flexible printed circuit board, is a circuit board made of a flexible base material. Compared with a traditional rigid circuit board, the flexible circuit board has flexibility and bendability, and then may meet application requirements of complex curved surfaces and narrow spaces. Therefore, the flexible circuit boards are widely used in various fields, such as consumer electronic products (such as smart phones and tablet computers), automotive electronics, medical devices, aerospace, and the like. They can meet the requirements for compact, light-thin, and multifunctional electronic devices, and exhibit a good property and reliability in severe environments, such as high temperature, high humidity, high vibration, etc.

In a display panel, it is usually necessary to use a surface mount technology to realize an electrical connection between the flexible circuit board and an electronic element. However, when an electronic element is soldered to a relatively thin flexible circuit board (for example, a flexible circuit board with less than three layers) mainboard through the surface mount technology, concave-convex uneven mold marks often appear in a soldering region of the flexible circuit board, and the mold marks may be further transmitted to other film layer of the display panel through the flexible circuit board, thereby not only affecting an aesthetics of the flexible circuit board, but also possibly affecting the property of a device in a region where the flexible circuit board is located.

### SUMMARY

The present disclosure provides a flexible circuit board, a display panel, and a display apparatus to solve defects in the related art.

According to a first aspect of the embodiments of the present disclosure, a flexible circuit board is provided. The flexible circuit board includes: a substrate, one or more electronic elements, and an adhesive layer; where the substrate includes one or more device regions on an upper surface of the substrate, and the electronic elements are fixed in the device regions; the adhesive layer is fixed to a lower surface of the substrate; and the adhesive layer includes an adhesive portion and one or more cavity portions formed by hollowing out a part of the adhesive portion, and the cavity portions are located below the device regions.

Further, the number of the device regions is same as the number of the cavity portions, and the cavity portions are provided below the device regions in a one-to-one correspondence.

Further, for each of the cavity portions, an area of the cavity portion is greater than or equal to an area of a device region corresponding to the cavity portion.

Further, the adhesive portion includes a first adhesive sub-portion, a second adhesive sub-portion, and a third adhesive sub-portion; the first adhesive sub-portion and the second adhesive sub-portion are respectively located on a left side and a right side of the cavity portions, and the left side and the right side of the cavity portions are opposite to each other, the third adhesive sub-portion is located below the cavity portion, and the first adhesive sub-portion, the second adhesive sub-portion, and the third adhesive sub-portion enclose a cavity as the cavity portion.

Further, the flexible circuit board further includes a grounding portion, where the lower surface of the substrate is provided with a groove, and the grounding portion is provided in a cavity enclosed by the groove and is located above the adhesive layer.

Further, the flexible circuit board further includes a filling adhesive, where there is a gap between the grounding portion and the adhesive layer, and the filling adhesive is provided in the gap and fills the gap to electrically connect the grounding portion to the adhesive layer.

Further, an area of the grounding portion is greater than an area of the filling adhesive.

Further, the grounding portion is located above the adhesive portion.

Further, the grounding portion is located above the cavity portions.

Further, the flexible circuit board further includes an elastic conductor provided in the cavity portions and electrically connected to the filling adhesive.

Further, the elastic conductor includes a shell and a filler, the shell encloses a cavity, the filler is provided in the cavity, and the shell is electrically connected to the filling adhesive.

Further, the shell is a conductive cloth, and the filler is a foam.

Further, the substrate is formed by stacking layers of conductive base materials, and the number of the layers is less than six.

Further, the conductive base materials are metal copper, and the number of the layers included in the substrate is two.

According to a second aspect of embodiments of the present disclosure, a display panel is provided. The display panel includes the above flexible circuit board.

According to a third aspect of embodiments of the present disclosure, a display apparatus is provided. The display apparatus includes the above display panel.

It can be seen from the above embodiments that providing the cavity portions below the device regions, can avoid the concave-convex marks on the lower surface of the substrate from being transmitted to other film layers, due to the generation of the concave-convex marks on the lower surface of the substrate when the electronic elements are fixed in the device regions through the surface mount technology, which can improve the aesthetics of the product.

It should be understood that the above general description and the detailed description in the following text are only exemplary and explanatory, and cannot limit the present disclosure.

### BRIEF DESCRIPTION OF DRAWINGS

The accompanying drawings herein are incorporated into the specification and form a part of this specification, show embodiments conforming to the present disclosure, and are used to explain principles of the present disclosure together with the specification.

FIG. 1 is a schematic front view of a flexible circuit board shown according to an embodiment of the present disclosure.

FIG. 2 is a schematic back view of the flexible circuit board shown in FIG. 1.

FIG. 3 is a schematic cross-sectional view of the flexible circuit board shown in FIG. 2.

FIG. 4 is a schematic diagram of another embodiment of the flexible circuit board shown in FIG. 3.

FIG. 5 is a cross-sectional view of a grounding portion of the flexible circuit board shown in FIG. 3.

FIG. 6 is a schematic back view of still another embodiment of the flexible circuit board shown in FIG. 1.

FIG. 7 is a schematic cross-sectional view of the flexible circuit board shown in FIG. 6.

FIG. 8 is a cross-sectional view of a grounding portion of the flexible circuit board shown in FIG. 7.

Reference signs: 10. substrate; 11. device region; 20. electronic element; 30. adhesive layer; 31. adhesive portion; 311. first adhesive sub-portion; 312. second adhesive sub-portion; 313. third adhesive sub-portion; 32. cavity portion; 40. grounding portion; 50. filling adhesive; 60. elastic conductor; 61. shell; 62. filler; 70. bonding pin; 80. board-to-board connector; 81. header; 82. socket; and 90. SCF layer.

### DETAILED DESCRIPTION

Exemplary embodiments will be described in details herein, with examples thereof represented in the accompanying drawings. When the following description involves the accompanying drawings, same numerals in different figures represent same or similar elements unless otherwise indicated. Implementations described in the following exemplary embodiments do not represent all implementations consistent with the present disclosure. Rather, they are only examples of apparatuses and methods that are consistent with some aspects of the present disclosure as detailed in the attached claims.

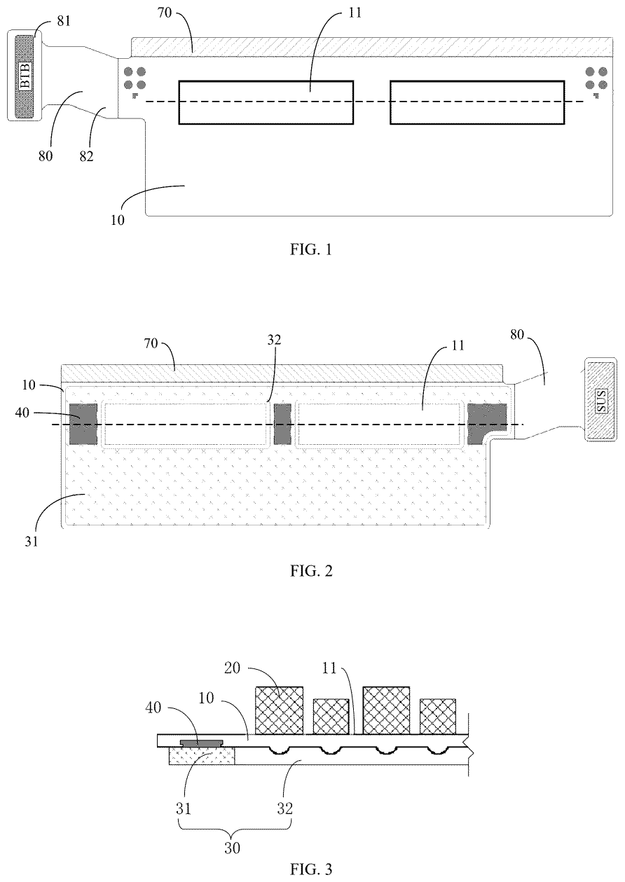

Referring to FIG. 1 to FIG. 3, the present disclosure provides a flexible circuit board. The flexible circuit board may include a substrate 10, one or more electronic elements 20, and an adhesive layer 30. The substrate 10 may include one or more device regions 11. The device regions 11 may be located on an upper surface of the substrate 10, and the electronic elements 20 are fixed in the device regions 11. Generally, the electronic elements 20 are mounted in the device regions 11 through a surface mount technology (SMT), and the electronic elements 20 are basic components constituting electronic equipment and circuits. In the present disclosure, the electronic elements 20 may include a resistor for controlling a current, dividing voltage, matching impedance, a capacitor for storing charges and releasing energy, an inductor for storing magnetic energy and resisting current variation, an integrated circuit with a plurality of electronic elements integrated together, and the like.

The adhesive layer 30 may be fixed to or provided on a lower surface of the substrate 10. The adhesive layer 30 may be a conductive adhesive, and the area of the adhesive layer 30 is less than or equal to the area of the substrate 10, to ensure that the substrate 10 is not prone to falling off when the substrate 10 is attached to other film layers through the adhesive layer 30, thereby improving the attachment strength. In the present disclosure, the conductive adhesive is an adhesion agent with an electrical conductivity, and is commonly used for applications, such as connections between electronic devices, conductive filling, shielding, etc.

The conductive adhesive applied in the embodiment of the present disclosure includes: a silver paste conductive adhesive that is formed by suspending silver particles in the adhesive base and has higher electrical conductivity and current carrying capacity; a carbon paste conductive adhesive that is formed by suspending carbon particles in the adhesive base, has electrical conductivity inferior to the silver paste, but is more economical, and is commonly used for low-cost circuit connections and conductive filling; a conductive tape that is an adhesive tape made of a special conductive material, may provide a current conduction path, and is a conductive tape commonly used for connecting a flexible circuit, a conductive wiring, etc.; a conductive adhesion agent that is made by mixing conductive materials (such as carbon fiber, metal particles, etc.) with the adhesion agent, and is commonly used for circuit connections, repairing conductive paths, etc.; a copper paste conductive adhesive that is made by suspending copper particles in the adhesive base, has good electrical conductivity and current carrying capacity, and is commonly used in applications, such as connections, conductive filling, etc.; etc.

The adhesive layer 30 may include an adhesive portion 31 and one or more cavity portions 32 formed by hollowing out a part of the adhesive portion 31. The cavity portions 32 are located below the device regions 11. “The cavity portions 32 being located below the device regions 11” herein may include a plurality of cases. In a first case, a region corresponding to the cavity portions 32 completely covers a region corresponding to the device regions 11, that is, a projection of the device regions 11 in a vertical direction completely falls into a projection of the cavity portions 32 in the vertical direction, or the projection of the device regions 11 in the vertical direction is completely consistent with the projection of the cavity portions 32 in the vertical direction. In a second case, the region corresponding to the cavity portions 32 partially overlaps the region corresponding to the device regions 11, that is, a part of the projection of the device regions 11 in the vertical direction falls into the projection of the cavity portions 32 in the vertical direction.

When the electronic elements 20 are fixed to the device regions 11 through the surface mount technology, the lower surface of the substrate 10 will generate concave-convex marks as shown in FIG. 3. In a conventional flexible circuit board, the amount of deformation transmitted by the concave-convex marks to the adhesive layer 30 is also relatively large, which will greatly affect flatness of an attaching interface of the flexible circuit board. In addition, the concave-convex marks are further transmitted through the substrate 10 and the adhesive layer 30 to film layers or devices located below the flexible circuit board. When these underlying film layers or devices are sensitive to an external force, they are more likely to be damaged due to the concave-convex marks.

The concave-convex marks are generated when the electronic elements 20 are fixed to the device regions 11 through the SMT technology. The concave-convex marks are mainly located on the lower surface of the substrate 10 and are directly below the device regions 11. Therefore, in the embodiment of the present disclosure, a solid part of the adhesive layer 30 below the device regions 11 is removed to form the cavity portions 32, and the concave-convex marks cannot be transmitted to other film layers connected to the adhesive layer 30, thereby avoiding affecting the aesthetics of the flexible circuit board and the morphology of the underlying film layers. At the same time, generally, the area of the region where the device regions 11 are located on the substrate 10 has a relatively small proportion, so the area removed from the adhesive layer 30 directly below the device regions 11 will not affect an attaching strength for attaching the flexible circuit board to other film layers.

The substrate 10 in the embodiment of the present disclosure may be formed by stacking layers of conductive base materials, and the number of the layers is less than six. For the conventional flexible circuit board, a substrate is formed generally by stacking six layers of conductive base materials, which has better overall strength, and the concave-convex marks generated when the electronic elements 20 are fixed to the device regions 11 through the SMT technology are also smaller. However, the thickness of the substrate formed by stacking the six layers of conductive base materials is relatively high, which is not conducive to the development of light-thin flexible circuit boards. Meanwhile, since more layers of conductive base materials are stacked, the material cost and the processing cost are also relatively high, which is not conducive to expanded production.

Therefore, preferably, in an embodiment shown in the present disclosure, the number of the layers included in the substrate 10 is two, and the substrate 10 is formed by stacking metal copper as a base material. In the embodiment of the present disclosure, the base material of the flexible circuit board may be formed by providing a conductive metal in a flexible polymer material. The flexible polymer material includes:
a polyester film; where a polyester base material has a higher mechanical property and electrical property, and is suitable for some low-cost and medium-low density wiring applications;
a polyamide film; where a polyamide base material has a better high-temperature resistance property and mechanical strength, and is suitable for some applications in a high-temperature environment;
a polytetrafluoroethylene film (PTFE); where a PTFE base material has an excellent high-temperature resistance property, chemical stability, and electrical insulation property, and is suitable for some applications requiring extremely high reliability and special environments; and/or
a polyether ketone film (PEEK); where a PEEK base material has a higher heat resistance property, mechanical strength, and chemical stability, and is suitable for some applications in a high-temperature and high-pressure environment.

The above base materials are only some common types of base materials, and the embodiment shown in the present disclosure is not limited to the above base materials, and may also refer to other not-listed base materials suitable for manufacturing the substrate 10 of the flexible circuit board.

In the embodiment of the present disclosure, the base material of the substrate 10 may be composed of the following base layers in sequence: a polyester film, as a flexible base material of the substrate 10 of the flexible circuit board, where the polyester film has a better mechanical property and electrical property, may provide an ability to resist bending and stretching, and also has a certain insulation property; a copper foil, as a conductive layer, where the copper foil is located on the surface of the polyester film, and can provide the substrate 10 of the flexible circuit board with a conductive function required for circuit wiring, and usually, there may be one or more layers of copper foils on the substrate 10 of the flexible circuit board for transmitting signals, power supplying, ground wires, etc.; and a cover film layer (or coverlay), which is a protective layer covering the surface of the copper foil, usually made of a polyester film or a polyamide film, and may provide additional mechanical protection and insulation property to prevent the copper foil layer from being damaged.

The above embodiment is only one of the embodiments of the substrate 10 shown in the embodiments of the present disclosure, and other materials having the same property may also be used as alternatives to form the material of the substrate 10 shown in the embodiments of the present disclosure.

A plurality of device regions 11 may be generally provided on the substrate 10. In order to ensure that the concave-convex marks generated when all the electronic elements 20 are fixed to the device regions 11 through the SMT technology do not affect the attaching of the flexible circuit board to other film layers, the number of the device regions 11 is the same as the number of the cavity portions 32, the cavity portions 32 are provided below the device regions 11 in a one-to-one correspondence, and the area of each of the cavity portions 32 may be greater than or equal to the area of the device region 11 corresponding to the cavity portion.

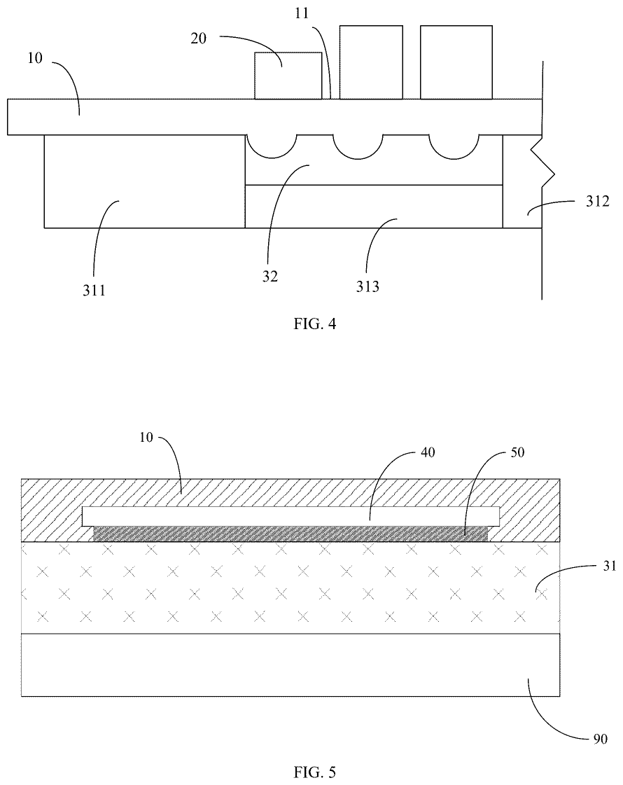

Referring to FIG. 4, in an embodiment, the adhesive portion 31 includes a first adhesive sub-portion 311, a second adhesive sub-portion 312, and a third adhesive sub-portion 313. The first adhesive sub-portion 311 and the second adhesive sub-portion 312 are respectively located on a left side and a right side of the cavity portions 32, where the left side and the right side of the cavity portions 32 are opposite to each other. The third adhesive sub-portion 313 is located below the cavity portions 32, and the first adhesive sub-portion 311, the second adhesive sub-portion 312, and the third adhesive sub-portion 313 enclose a cavity as the cavity portions 32.

In order to ensure that the concave-convex marks generated when all the electronic elements 20 are fixed to the device regions 11 through the SMT technology do not affect the attaching of the flexible circuit board to other film layers, in this embodiment, the thicknesses of the cavity portions 32 should be greater than the thicknesses of all the concave-convex marks.

Referring to FIG. 5, the flexible circuit board provided in the present disclosure further includes a grounding portion 40. The lower surface of the substrate 10 is provided with a groove, and the grounding portion 40 is provided in a cavity enclosed by the groove and is located above the adhesive layer 30.

Grounding, as a common way in electronic equipment and circuits, can provide safety protection for the flexible circuit board and the electronic elements 20 provided on the flexible circuit board, and safely release dangerous charges, such as static charges, electric leakage, etc., that may be accumulated by the device to the ground, to avoid the risk of electric shock to the human body or fire. The grounding may help to suppress electromagnetic interference. Because the electronic equipment generates certain electromagnetic radiation when working, and is also subject to the electromagnetic interference from the external environment, through an effective grounding design, the electromagnetic radiation and interference may be guided to the ground, which reduces the influence on other devices and systems. The grounding helps to improve the stability and property of the circuit. Through the grounding, a stable reference potential may be formed, to reduce the interference and instability between signal interfaces. The grounding can prevent accumulation and release of static electricity. The static electricity is a common phenomenon when the electronic equipment contacts or rubs with the human body, and may cause circuit damage or data loss. Through a good grounding design, the static charges may be safely guided to the ground, which reduces the influence on the device and the circuit.

In the embodiment shown in the present disclosure, the base material of the substrate 10 in the embodiment of the present disclosure is formed by covering the polyester film on the copper foil. The polyester film has the insulation property, so that in order to enable the substrate 10 to be grounded, the copper foil is exposed to form the grounding portion 40 by chemical-corrosion or mechanically removing the polyester film from the surface of the substrate 10.

Since the groove is formed by chemical-corrosion or mechanically removing the polyester film from the surface of the substrate 10, the grounding portion 40 is located in the groove, and there is a gap between the grounding portion 40 and the adhesive layer 30, the grounding portion 40 cannot be electrically connected to the adhesive layer 30 due to the presence of the gap, and then cannot be grounded.

Therefore, the flexible circuit board provided by the present disclosure further includes a filling adhesive 50. The filling adhesive 50 is provided in the gap and fills the gap to electrically connect the grounding portion 40 to the adhesive layer 30. Generally, an area of the grounding portion 40 is greater than an area of the filling adhesive 50. The filling adhesive 50 is a filling level-difference conductive adhesive.

The filling level-difference conductive adhesive is an adhesion agent used to repair or create conductive connections. The filling level-difference conductive adhesive typically consists of a conductive filling material (e.g., silver, copper, carbon nanotubes, etc.) and an adhesion agent matrix. The filling level-difference conductive adhesive is widely used in the electronic field, for repairing broken wires on circuit boards, repairing conductive wires on touch screens, and creating conductive connections between electronic parts. The main function of the filling level-difference conductive adhesive is to provide good electrical conductivity and gluing property. When a wire on the flexible circuit board is broken, the broken part may be filled with the filling level-difference conductive adhesive, so that the connectivity of the circuit is recovered. The adhesion agent has higher electrical conductivity, may effectively transmit currents, and forms a reliable conductive path. The filling level-difference conductive adhesive may also be used to repair a conductive circuit on the touch screen. By coating the filling level-difference conductive adhesive on the broken conductive circuit, the circuit connection may be re-established, so that the touch screen works normally again. In addition, the filling level-difference conductive adhesive may also be used to create conductive connections between electronic devices. For example, in a process of assembling an electronic element, if a reliable conductive connection between two parts is required, the filling level-difference conductive adhesive may be used for gluing, thereby implementing current transmission.

The selection of the filling level-difference conductive adhesive should be determined according to specific application requirements. Different filling level-difference conductive adhesives have different electrical conductivity, gluing properties, and durability. Therefore, before use, it is necessary to carefully select a filling level-difference conductive adhesive suitable for a specific application, and perform the correct operation according to the instructions for use provided by the manufacturer.

In this embodiment, the filling adhesive 50 and the adhesive layer 30 may be the same conductive adhesive or different conductive adhesives. The type of the conductive adhesive used as the filling adhesive 50 has been described for the adhesive layer 30, and thus will not be repeated.

The flexible circuit board may further include a shielding layer 90. The shielding layer 90 may be a shield copper foil (SCF) layer, and the shielding layer 90 is located below and connected to the adhesive layer 30. The SCF layer is a layer of specially treated copper foil applied on a flexible circuit board (FPC) or a rigid circuit board.

The shielding layer 90 has the following main characteristics and uses.

The shielding layer 90 may provide electromagnetic shielding protection to prevent external electromagnetic signals from interfering with the circuit, so as to ensure the stability and reliability of the circuit. Due to the good electrical conductivity of the copper, the shielding layer 90 may be used to provide a current conduction path, to ensure normal working of the circuit. The shielding layer 90 is usually very thin, can adapt to the compact design of the circuit board, and does not occupy too much space. The shielding layer 90 may be combined with other circuit layers (such as a signal layer, a power layer, etc.) to realize the high integration and compact layout of the circuit.

The preparation of the shielding layer 90 generally includes the following key steps:
copper foil selection; where a high-purity copper foil is selected as a raw material to ensure good electronic conductivity and reliability;
surface treatment; where the surface of the copper foil is specially treated, such as chemical treatment, mechanical polishing, to improve the flatness and adhesive force of the surface;
a preparation process; where the shielding layer 90 is combined with the plate material of the substrate 10 of the flexible circuit board through processes, such as shielding copper plating, gluing, lamination, etc. In the embodiment shown in the present disclosure, the shielding layer 90 is connected to the adhesive layer 30.

The shielding layer 90 is widely used in electronic products in various fields, such as communication devices, consumer electronic products, automobile electronics, etc. The shielding layer may effectively reduce the electromagnetic interference, improve the stability and property of the circuit, and ensure the normal working of the device.

Referring to FIG. 1 to FIG. 5, the grounding portion 40 is located above the adhesive portion 31. The grounding portion 40 is electrically connected to the adhesive portion 31 through the filling adhesive 50.

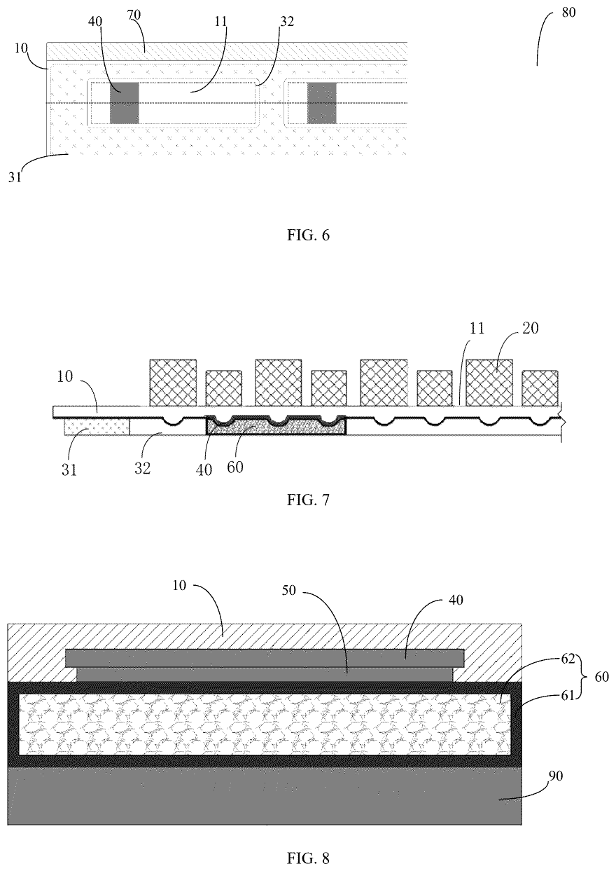

Referring to FIG. 6 to FIG. 8, in another embodiment, the grounding portion 40 is located above the cavity portions 32. Due to the presence of the cavity portions 32, the grounding portion 40 cannot be connected to the adhesive portion 31 through the filling adhesive 50, so the flexible circuit board further includes an elastic conductor 60 provided in the cavity portions 32 and electrically connected to the filling adhesive 50 and the shielding layer 90.

In an embodiment, the elastic conductor 60 may include a shell 61 and a filler 62. The shell 61 encloses a cavity, and the filler 62 is provided in the cavity. The shell 61 is electrically connected to the filling adhesive 50, so that a current can flow from the grounding portion 40, through the filling adhesive 50 and the shell 61, to the shielding layer 90.

In order to ensure that the concave-convex marks generated when the electronic elements 20 are fixed to the device regions 11 through the SMT technology does not affect the attaching of the flexible circuit board to other film layers, in this embodiment, the shell 61 is a conductive cloth, the filler 62 is a foam. The foam has a compressible characteristic, so that transmission of the concave-convex marks press the foam as the filler 62 through contact with the shell 61, and the foam deforms under the action of the force, thereby avoiding transmitting the concave-convex marks to the shielding layer 90.

The conductive cloth is a material for electromagnetic shielding and has good electrical conductivity and anti-interference property. Depending on different application scenarios and requirements, the conductive cloth may use different materials and manufacturing processes.

There are several common conductive cloths below.

One is a silver fiber conductive cloth. The silver fiber conductive cloth uses a fiber material as a carrier, where the silver fiber is a key component for conducting electricity. The silver fiber conductive cloth has excellent electrical conductivity and anti-interference property, and is suitable for electromagnetic shielding in the field of high frequency and microwave.

One is a copper foil conductive cloth. The copper foil conductive cloth uses the copper foil as a carrier, and may be woven by steel wires or copper wires to enhance its mechanical property. The copper foil conductive cloth has good electrical conductivity and oxidation resistance property, and is suitable for electromagnetic shielding in the field of low frequency and medium frequency.

One is a conductive coating cloth. For the conductive coating cloth, a conductive material (such as copper, silver, etc.) is coated on the surface of the base fabric, and different coating thicknesses and manners may be used as required. The conductive coating cloth has good electrical conductivity and shear resistance property, and is suitable for electromagnetic shielding of various complex shapes.

One is a carbon fiber conductive cloth. The carbon fiber conductive cloth uses the carbon fiber as a carrier and has lightweight, high strength, and good electrical conductivity. The carbon fiber conductive cloth is suitable for electromagnetic shielding in severe environments, such as high temperature, high humidity, etc., for example aerospace, automobiles, and other fields.

The foam is a common polymer material, has characteristics, such as sound absorption, sound insulation, shock resistance, etc., and is widely applied in fields, such as packaging, sound insulation and shock absorption, protection, etc. There are several common foams below.

One is a polyethylene (PE) foam. The polyethylene foam is a lightweight and soft froth material, has excellent sound absorption, sound insulation, and shock resistance properties, and also has certain flexibility and elasticity. The polyethylene foam is commonly used in fields, such as electronic product packaging, logistics protection, etc.

One is a polyurethane (PU) foam. The polyurethane foam is a high-density, wear-resistant, and pressure-resistant froth material, and has good shock absorption property and durability. The polyurethane foam is commonly used in fields, such as mechanical devices, automotive trim, sport equipment, etc.

One is a polystyrene foam. The polystyrene foam is also known as an expandable polystyrene (EPS), is a lightweight and fluffy froth material, and has good energy absorption and heat insulation properties. The polystyrene foam is commonly used in fields, such as heat preservation in building, packaging filling material, etc.

One is a polyester (PET) foam. The polyester foam is a high-density froth material, has good pressure resistance and durability, and also has an excellent hygroscopic property. The polyester foam is commonly used in fields, such as electronic product packaging, medical equipment protection, etc.

In the embodiment shown in the present disclosure, the conductive cloth and the foam may be selected from any one or combination of the above conductive cloths and the foams, which is not limited in the present disclosure, and only the selected material of the conductive cloth is required to have the electrical conductivity, and the selected material of the foam is required to have a characteristic of being elastically deformable.

In the embodiment shown in the present disclosure, the flexible circuit board further includes a bonding pin 70 and a board-to-board (BTB) connector.

The bonding pin 70 refers to a metal lead used to connect pins of a chip to pins of a package base during packaging of a semiconductor chip (such as an integrated circuit). They play an important role in electrically connecting the chip to the package base.

In the semiconductor packaging process, a circuit pin of the chip needs to be reliably connected to the pins of the package base, to realize signal transmission and power supply. This requires the use of the soldering lead to connect the pins of the chip to the pins of the package base. The soldering lead is typically made of a metallic material, such as copper, aluminium, etc.

The soldering lead is connected to the pins of the chip and the pins of the package base by a series of process steps. A typical process includes the following steps.

Pins is arranged. The chip is correctly aligned with the package base and the matching of the pins is ensured.

Soldering is performed. Metal connections are formed between the pins of the chip and the pins of the package base by soldering tin or other soldering material. This may be accomplished by manners such as thermal pressure soldering, ultrasonic soldering, laser soldering, etc.

Crimping or ball limiting is performed. In certain types of the package, a soldering lead may need to be further secured by crimping or forming a soldering ball.

Cutting is performed. The soldering lead is cut into an appropriate length.

In the embodiment shown in the present disclosure, the bonding pins 70 mainly function to connect the electronic elements 20 and the wire, and provide a reliable connection point on the flexible circuit board to implement the electrical connection. The bonding pins 70 are generally used for following several main functions.

The electronic elements 20 are connected. The bonding pin 70 provides a fixed position for the electronic element 20 (e.g., resistor, capacitor, chip, etc.), and the electronic element 20 is electrically connected to the flexible circuit board through soldering. The bonding pins 70 have a certain width and spacing on the circuit board, which facilitates the soldering operation and ensures the soldering quality.

Electrical signals are conducted. The bonding pins 70 are connected by soldering, and may conduct electrical signals from the electronic elements 20 to other circuit paths on the flexible circuit board to realize signal transmission. The electrical conductivity of the bonding pins 70 determines the stability and reliability of the circuit.

Mechanical support is provided. The bonding pins 70 may also provide mechanical support for the electronic elements 20, so that the electronic elements 20 are firmly fixed on the flexible circuit board. This is particularly important for the flexible circuit board because they need to have certain flexibility and bending resistance, and the presence of the bonding pins 70 may increase the connection strength and stability between the electronic elements 20 and the flexible circuit board.

Heat conduction and heat dissipation are performed. The bonding pin 70 may also play a role of heat dissipation when needed, and conduct heat generated by the elements to the flexible circuit board to achieve a heat dissipation effect. This is particularly important for elements with higher power, which may help maintain normal working temperatures of the elements.

In summary, the soldering lead is a metal pin used for connecting the pins of the chip to the pins of the package base in a process of packaging a semiconductor chip, and plays an important role in electrical connection and signal transmission. A polyvinyl chloride (PVC) foam is a hard and durable froth material and has a good waterproof property and chemical corrosion resistance property. The polyvinyl chloride foam is commonly used in fields, such as building sound insulation, floor shock absorption pad, etc.

The board-to-board connector is a device for electrically and mechanically connecting two or more circuit boards. The board-to-board connector is usually composed of a header and a socket. The header and the socket are respectively fixed on different circuit boards, and are connected to each other in a coordinated manner through the design of pin-slot.

The board-to-board connector is usually compact in design, has a large number of pins, may provide high interface density, and is suitable for an application requiring a plurality of signal transmissions.

The board-to-board connector provides reliable mechanical fixation in the process of connection, ensures the stability and reliability of the connection, and is suitable for various industrial and consumer electronic equipment.

The board-to-board connector transmits signals through the design of pin-slot, provides good electrical connection, and may transmit high-frequency, high-speed or other complex signals, to meet the requirements of different applications.

The board-to-board connector usually provides selection of a plurality of specifications and models, including the number of pins, the arrangement manner of the pins, the connection manner of the pins, etc., which may be selected and customized according to specific application requirements.

In this embodiment, the bonding pins 70 are located on one side of the substrate 10 and connected to the substrate 10. The board-to-board connector 80 includes a socket 82 and a header 81 extending from the socket 82. The socket 82 is connected to the substrate 10.

An embodiment of the present disclosure further provides a display panel, including a display module and the flexible circuit board in any one of the above embodiments.

An embodiment of the present disclosure further provides a display apparatus including the above display panel.

It should be noted that the display apparatus in this embodiment may be any product or part having a display function, such as an electronic paper, a mobile phone, a tablet computer, a television, a notebook computer, a digital photo frame, a navigator, etc.

It should be noted that dimensions of layers and regions may be exaggerated for clarity of illustration in the accompanying drawings. In addition, it can be understood that when an element or layer is referred to as being “on” another element or layer, the element or layer may be directly on the another element or layer, or there may be an intervening layer. In addition, it can be understood that when an element or layer is referred to as being “under” another element or layer, the element or layer may be directly under the another element or layer, or there may be more than one intervening layer or element. In addition, it can also be understood that when a layer or element is referred to as being “between” two layers or elements, the element or layer may be a unique layer between the two layers or elements, or there may also be more than one intervening layer or element. Similar reference signs indicate similar elements throughout.

In the present disclosure, the terms “first” and “second” are used solely for descriptive purposes and should not be understood as indicating or implying relative importance. The term “multiple/a plurality of” refer to two or more, unless explicitly defined otherwise.

Those skilled in the art will easily come up with other implementation solutions of the present disclosure after considering the specification and practicing the present disclosure disclosed herein. The present disclosure aims to cover any variations, uses, or adaptive changes of the present disclosure, which follow general principles of the present disclosure and include common knowledge or customary technical means in the art not disclosed in the present disclosure. The specification and embodiments are only considered exemplary, and the true scope and spirit of the present disclosure are indicated by the following claims.

It should be understood that the present disclosure is not limited to the precise structure described above and shown in the accompanying drawings, and various modifications and changes may be made without departing from its scope. The scope of the present disclosure is limited only by the appended claims.

1. A flexible circuit board, comprising a substrate, one or more electronic elements, and an adhesive layer,
wherein the substrate comprises one or more device regions on an upper surface of the substrate in a vertical direction, and the electronic elements are fixed in the device regions,
wherein the adhesive layer is fixed to a lower surface of the substrate in the vertical direction, and comprises an adhesive portion and one or more cavity portions formed by hollowing out a part of the adhesive portion, and
wherein the cavity portions are located below the device regions in the vertical direction.

2. The flexible circuit board of claim 1, wherein a number of the device regions is same as a number of the cavity portions, and the cavity portions are provided below the device regions in a one-to-one correspondence.

3. The flexible circuit board of claim 2, wherein for each of the cavity portions, an area of a projection of the cavity portion in the vertical direction is greater than or equal to an area of a projection of a device region corresponding to the cavity portion in the vertical direction.

4. The flexible circuit board of claim 3, wherein the adhesive portion comprises a first adhesive sub-portion, a second adhesive sub-portion, and a third adhesive sub-portion;
wherein the first adhesive sub-portion and the second adhesive sub-portion are respectively located on a left side and a right side of the cavity portions, and the left side and the right side of the cavity portions are opposite to each other;
wherein the third adhesive sub-portion is located below the cavity portion, and
wherein the first adhesive sub-portion, the second adhesive sub-portion, and the third adhesive sub-portion enclose a cavity as the cavity portion.

5. The flexible circuit board of claim 1, further comprising a grounding portion,
wherein the lower surface of the substrate is provided with a groove, and
wherein the grounding portion is provided in a cavity enclosed by the groove and is located above the adhesive layer.

6. The flexible circuit board of claim 5, further comprising a filling adhesive,
wherein there is a gap between the grounding portion and the adhesive layer, and
wherein the filling adhesive is provided in the gap and fills the gap to electrically connect the grounding portion to the adhesive layer.

7. The flexible circuit board of claim 6, wherein an area of a projection of the grounding portion in the vertical direction is greater than an area of a projection of the filling adhesive in the vertical direction.

8. The flexible circuit board of claim 6, wherein the grounding portion is located above the adhesive portion.

9. The flexible circuit board of claim 6, wherein the grounding portion is located above the cavity portions.

10. The flexible circuit board of claim 9, further comprising an elastic conductor provided in the cavity portions and electrically connected to the filling adhesive.

11. The flexible circuit board of claim 10, wherein the elastic conductor comprises a shell and a filler,
wherein the shell encloses a cavity, and the filler is provided in the cavity, and
wherein the shell is electrically connected to the filling adhesive.

12. The flexible circuit board of claim 11, wherein the shell is a conductive cloth, and the filler is a foam.

13. The flexible circuit board of claim 1, wherein the substrate is formed by stacking layers of conductive base materials, and a number of the layers is less than six.

14. A display panel, comprising the flexible circuit board of claim 1.

15. A display apparatus, comprising the display panel of claim 14.

16. The flexible circuit board of claim 13, wherein the conductive base materials are metal copper.

17. The flexible circuit board of claim 13, wherein the number of the layers comprised in the substrate is two.

18. The flexible circuit board of claim 2, wherein the substrate is formed by stacking layers of conductive base materials, and a number of the layers is less than six.

19. The flexible circuit board of claim 3, wherein the substrate is formed by stacking layers of conductive base materials, and a number of the layers is less than six.

20. The flexible circuit board of claim 4, wherein the substrate is formed by stacking layers of conductive base materials, and a number of the layers is less than six.
